(19) United States
(12) Patent Application Publication
(10) Pub. No.: US 2025/0194344 A1
(43) Pub. Date: Jun. 12, 2025

(54) DISPLAY DEVICE

(71) Applicant: Samsung Display Co., LTD., Yongin-si (KR)

(72) Inventors: Hyeon Bum LEE, Yongin-si (KR); Hyun Ho KIM, Yongin-si (KR); HYOENG-KI KIM, Yongin-si (KR)

(73) Assignee: Samsung Display Co., LTD., Yongin-si (KR)

(21) Appl. No.: 18/750,038

(22) Filed: Jun. 21, 2024

(30) Foreign Application Priority Data
Dec. 11, 2023 (KR) 10-2023-0179125

(51) Int. Cl. H10K 59/122; H10K 59/80

(52) U.S. Cl. CPC H10K 59/122; H10K 59/80515

(57) ABSTRACT

A display device includes a plurality of first pixels and a plurality of second pixels alternately arranged, and a driver that drives the plurality of first pixels and the plurality of second pixels by individually applying a driving signal and a voltage, each of the plurality of first pixels includes a first transistor and a first pixel electrode electrically connected to the first transistor, each of the plurality of second pixels includes a second transistor and a second pixel electrode electrically connected to the second transistor, and the first pixel electrode and the second pixel electrode have different shapes from each other in a cross-sectional view.

### CROSS-REFERENCE TO RELATED APPLICATION(S)

This application claims priority to and the benefits of Korean Patent Application No. 10-2023-0179125 under 35 U.S.C. § 119, filed on Dec. 11, 2023 in the Korean Intellectual Property Office, the entire contents of which are incorporated herein by reference.

### BACKGROUND

### 1. Technical Field

Embodiments relate to a display device.

### 2. Description of the Related Art

A display device includes pixels, which are units for displaying images. Each pixel of the display device that includes light emitting diodes among various display devices includes a light emitting diode that includes a cathode, an anode, and a light emitting diode, and a pixel circuit that includes transistors and at least one capacitor for driving the light emitting diode. The pixel circuit is connected to various signal lines and voltage lines, such as data lines and driving voltage lines.

### SUMMARY

Users may need a display device that displays images under different conditions according to the usage environment. For example, a display device that normally displays images with a wide viewing angle may be required, but when images are displayed, the users do not want to share the images with others, such as personal information, in a public place. Thus, a display device that displays images with a narrower viewing angle may be required.

Embodiments provide a display device that displays images under various conditions, such as different viewing angles, while reducing image quality degradation, such as color shift, by improving the degradation of luminance ratio characteristics due to changes in viewing angles.

However, embodiments are not limited to those set forth herein. The above and other embodiments will become more apparent to one of ordinary skill in the art to which the disclosure pertains by referencing the detailed description of the disclosure given below.

A display device according to an embodiment may include a plurality of first pixels and a plurality of second pixels alternately arranged, and a driver that drives the plurality of first pixels and the plurality of second pixels by individually applying a driving signal and a voltage, each of the plurality of first pixels may include a first transistor and a first pixel electrode electrically connected to the first transistor, and the second pixel may include a second transistor and a second pixel electrically connected to the second transistor, it may include an electrode, and the first pixel electrode and the second pixel electrode have different shapes in a cross-sectional view.

A display device according to an embodiment may include a plurality of first pixels and a plurality of second pixels alternately arranged, and a light blocking layer, and a plane of the light blocking layer corresponding to each of the plurality of first pixels or defining an edge portion of the first pixel, the shape or a width is different from the planar shape or a width of the light blocking layer corresponding to the second pixel, and each of the plurality of first pixels may include a first transistor and a first pixel electrode electrically connected to the first transistor, while the second pixel may include a second transistor and a second pixel electrode electrically connected to the second transistor, and the first pixel electrode and the second pixel electrode have different shapes in a cross-sectional view.

The first pixel electrode may include at least one curved portion in a cross-sectional view.

The first pixel electrode may include a flat portion extending in a first direction, and an inclined portion connected to the flat portion and slanted with respect to the first direction.

The inclined portion may be disposed along an edge portion of the first pixel electrode.

The second pixel electrode may include a flat portion extending in the first direction.

The first insulating layer disposed on the first transistor and the second transistor, and the second insulating layer disposed on the first insulating layer, and the second insulating layer may have a first opening overlapping the first pixel electrode.

The inclined portion of the first pixel electrode may be positioned on a side surface of the second insulating layer defining the first opening.

The display device may further include a pixel insulating layer positioned on the second insulating layer, and the pixel insulating layer may have a second opening overlapping the first pixel electrode and the second pixel electrode.

Each of plurality of the first pixels and each of the plurality of second pixels may include a plurality of sub-pixels displaying light of different colors, and each of the plurality of sub-pixels disposed in each of the plurality of first pixels may include the first pixel electrode, the first pixel electrode included in at least some of the plurality of sub-pixels included in each of the plurality of first pixels may include the inclined portion.

The display device may further include a first insulating layer disposed above the first transistor and the second transistor, a concave portion overlapping the first pixel electrode may be formed on an upper surface of the first insulating layer, and the inclined portion of the first pixel electrode may be disposed on the side surface of the concave portion.

According to embodiments, it is possible to provide a display device that displays images under various conditions, such as different viewing angles, while reducing image quality degradation such as color shift by improving the degradation of luminance ratio characteristics due to changes in viewing angles.

### BRIEF DESCRIPTION OF THE DRAWINGS

FIG. 1 is a schematic plan view of a display device according to an embodiment.

FIG. 2 is a schematic plan view of a display area of a display device according to an embodiment.

FIG. 3 is a schematic cross-sectional view of the display device shown in FIG. 2 taken along line A1-A2.

FIG. 4 is a schematic cross-sectional view of the display device shown in FIG. 2 taken along line B1-B2.

FIG. 5 is a schematic cross-sectional view of a light emitting device of a display device according to an embodiment.

FIG. 6 is a schematic cross-sectional view of the display device shown in FIG. 2 taken along line A1-A2, showing light emitted from the front of the display device in a normal mode.

FIG. 7 is a schematic cross-sectional view of the display device shown in FIG. 2 taken along line A1-A2, showing light emitted from the front of the display device in a private mode.

FIG. 8 is a schematic cross-sectional view of the display device shown in FIG. 2 taken along line A1-A2, showing light emitted to the side in a normal mode.

FIG. 9 is a graph showing the luminance ratio according to the viewing angle of an image displayed by a display device according to an embodiment and a comparative example.

FIG. 10 is a schematic cross-sectional view of the display device shown in FIG. 2 taken along line A1-A2.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

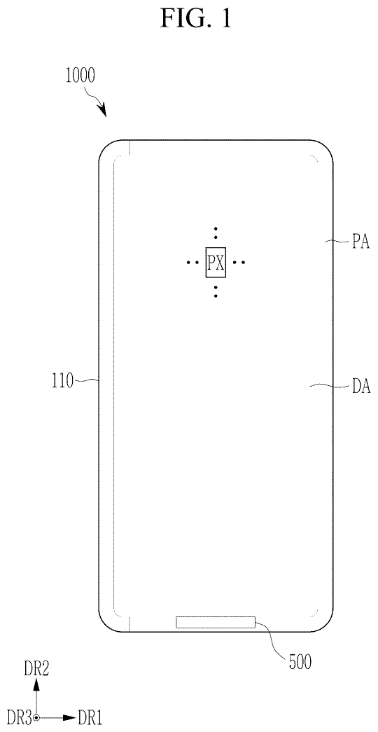

The structure of a display device according to an embodiment will be described with reference to FIGS. 1 to 5.

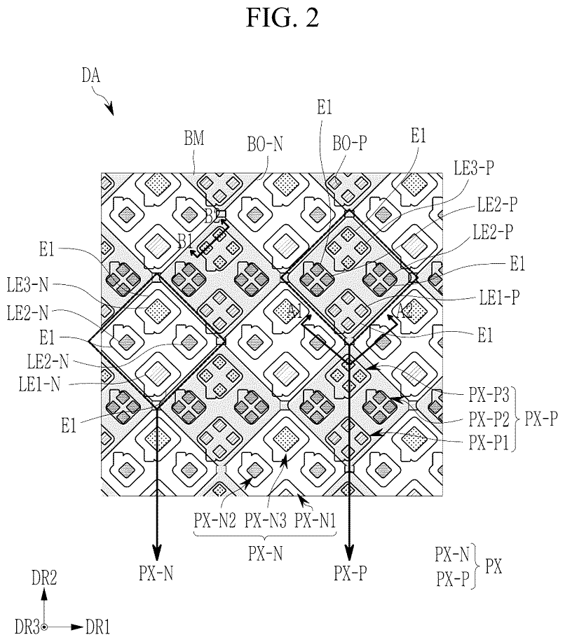

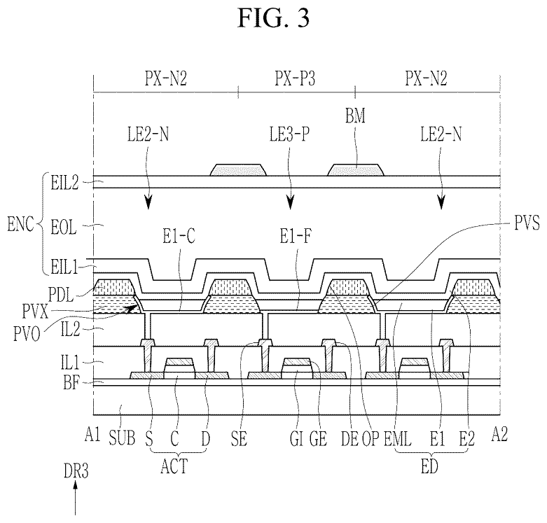

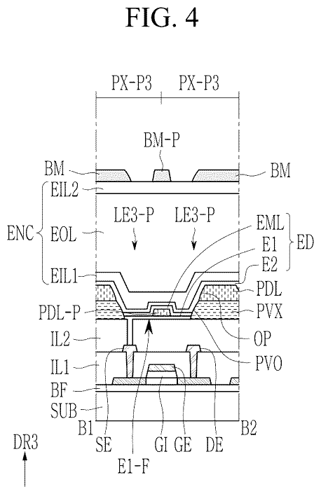

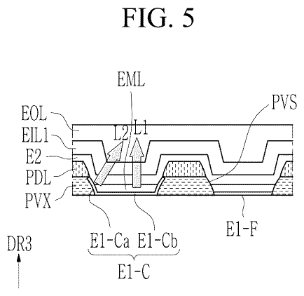

FIG. 1 is a schematic plan view of a display device according to an embodiment, FIG. 2 is a schematic plan view of a display area of a display device according to an embodiment, and FIG. 3 is a schematic plan view of the display device shown in FIG. 2 along line A1-A2. FIG. 4 is a schematic cross-sectional view of the display device shown in FIG. 2 taken along line B1-B2, and FIG. 5 is a schematic cross-sectional view of a light emitting device of the display device according to an embodiment.

Referring to FIG. 1, a display device 1000 according to an embodiment may include a display panel 110 that includes a display area DA capable of displaying an image, and a peripheral area PA around the display area DA. The display area DA may include pixels PX, which are units for displaying an image, and the peripheral area PA may or may not display an image. The peripheral area PA may surround the display area DA, but embodiments are not limited thereto.

The display area DA may have a display surface parallel to the first direction DR1 and the second direction DR2. The normal direction of the display surface on which an image is displayed, e.g., the thickness direction of the display panel 110, may be parallel to the third direction DR3.

The display panel 110 may be a rigid display panel, but embodiments are not limited thereto and may be a flexible display panel. The display panel 110 may be a light emitting display panel including a light emitting device, but the type of the display panel 110 is not limited thereto and may be various. For example, the display panel 110 may include a micro light emitting diode display panel, a quantum dot light emitting diode display panel, a quantum dot organic light emitting diode display panel, etc.

The display device 1000 according to an embodiment may include at least one driver 500 positioned on the front of the peripheral area PA of the display panel 110 or on the back of the display panel 110. The driver 500 may transmit a driving voltage and a driving signal to the pixel PX through various voltage lines and signal lines of the display panel 110. The driver 500 may be in the form of a flexible printed circuit film, a printed circuit board, or at least one driver circuit chip.

Referring to FIG. 2, pixels PX positioned in the display area DA of the display device 1000 according to an embodiment may include first pixels PX-N and second pixels PX-P. The first pixels PX-N and the second pixels PX-P may be driven individually or independently according to a driving signal from the driver 500. For example, the driver 500 may apply a driving signal and voltage to the first pixels PX-N and the second pixels PX-P to be driven simultaneously to display an image. In another example, the driving signal and voltage may be applied only to the first pixels PX-N to drive only the first pixels PX-N to display an image only to the first pixels PX-N. In another example, the driving signal and voltage may be applied only to the second pixels PX-P to drive only the second pixels PX-P and display an image only in the second pixels PX-P.

The first pixels PX-N and the second pixels PX-P may be alternately arranged in the display area DA. For example, rows of the first pixels PX-N arranged in the first direction DR1 and rows of the second pixels PX-P arranged in the first direction DR1 may be alternately arranged in the second direction DR2. For example, rows of the first pixel PX-N arranged in the second direction DR2 and rows of the second pixel PX-P arranged in the second direction DR2 may be alternately arranged in the first direction DR1. The first pixels PX-N and the second pixels PX-P may be alternately arranged in a diagonal direction inclined with respect to (or between) the first direction DR1 and the second direction DR2.

According to an embodiment, the viewing angle characteristics of an image displayed by driving only first pixels PX-N or driving first pixels PX-N and second pixels PX-P together may be different from the viewing angle characteristics of an image displayed by driving only the second pixels PX-P. For example, the viewing angle of an image displayed by driving only first pixels PX-N or driving first pixels PX-N and second pixels PX-P together may be the viewing angle of the image displayed by driving only each second pixel PX-P may be larger.

A driving mode that widens the viewing angle by driving only first pixels PX-N or driving first pixels PX-N and second pixels PX-P together to display may be a normal mode (or wide-viewing angle mode), and a driving mode in which only second pixels PX-P are driven and displayed to make the viewing angle relatively narrow so that images including private information are displayed mainly toward the front of the display device 1000 may be a private mode (or narrow-viewing angle mode).

This difference in viewing angle characteristics may be due to a difference in the structure of each first pixel PX-N and the structure of each second pixel PX-P. These structural differences will be explained later.

The first pixels PX-N may be a normal pixel, and the second pixels PX-P may be a private pixel.

Referring to FIG. 2, each first pixel PX-N may include a first sub-pixel PX-N1, a second sub-pixel PX-N2, and a third sub-pixel PX-N3 that display different colors, and each second pixel PX-P may include a first sub-pixel PX-P1, a second sub-pixel PX-P2, and a third sub-pixel PX-P3 that display different colors. Each sub-pixel PX-N1, PX-N2, PX-N3, PX-P1, PX-P2, or PX-P3 may include a pixel circuit including at least one transistor and a light emitting device electrically connected to each other. Each light emitting device may include a pixel electrode E1 that receives a data voltage from the pixel circuit.

The first sub-pixel PX-N1 or PX-P1 may be a red pixel, the second sub-pixel PX-N2 or PX-P2 may be a green pixel, and the third sub-pixel PX-N3 or PX-P3 may be a blue pixel, but embodiments are not limited thereto.

The display area DA according to an embodiment may include light emitting areas corresponding to sub-pixels PX-N1, PX-N2, PX-N3, PX-P1, PX-P2, and PX-P3. The light emitting areas positioned in each first pixel PX-N may include a first light emitting area LE1-N, a second light emitting area LE2-N, and a third light emitting area LE3-N. The first light emitting area LE1-N may correspond to the first sub-pixel PX-N1, the second light emitting area LE2-N may correspond to the second sub-pixel PX-N2, and the third light emitting area LE3-N may correspond to the third sub-pixel PX-N3.

The light emitting areas positioned in each second pixel PX-P may include a first light emitting area LE1-P, a second light emitting area LE2-P, and a third light emitting area LE3-P. For example, the first light emitting area LE1-P may correspond to the first sub-pixel PX-P1, the second light emitting area LE2-P may correspond to the second sub-pixel PX-P2, and the third light emitting area LE3-P may correspond to the third sub-pixel PX-P3.

The planar area of a first light emitting area LE1-P positioned at each second pixel PX-P may be smaller than the planar area of a first light emitting area LE1-N positioned at each first pixel PX-N. The planar area of a second light emitting area LE2-P positioned at each second pixel PX-P may be smaller than the planar area of a second light emitting area LE2-N positioned at each first pixel PX-N. The planar area of a third light emitting area LE3-P positioned at each second pixel PX-P may be smaller than the planar area of a third light emitting area LE3-N positioned at each first pixel PX-N.

In each first pixel PX-N, each light emitting area LE1-N, LE2-N, or LE3-N may be positioned corresponding to each pixel electrode E1, and in each second pixel PX-P. A plurality of (for example, four each) light emitting areas LE1-P, LE2-P, and LE3-P may be positioned corresponding to each pixel electrode E1.

The planar area of the pixel electrode E1 of the first sub-pixel PX-P1 of the second pixel PX-P may be larger than the planar area of the pixel electrode E1 of the first sub-pixel PX-N1 of the first pixel PX-N, and the planar area of the pixel electrode E1 of the second sub-pixel PX-P2 of each second pixel PX-P may be larger than the planar area of the pixel electrode E1 of the second sub-pixel PX-N2 of each first pixel PX-N, and the planar area of the pixel electrode E1 of the third sub-pixel PX-P3 of the second pixel PX-P may be larger than the planar area of the pixel electrode E1 of the third sub-pixel PX-N3 of each first pixel PX-N.

The arrangement of pixel electrodes E1 of the sub-pixels PX-N1, PX-N2, and PX-N3 positioned at each first pixel PX-N may be similar to the arrangement of pixel electrodes E1 of sub-pixels PX-P1, PX-P2, and PX-P3 positioned at each second pixel PX-P (for example, in a diamond shape).

In a plan view, a light blocking layer BM may be positioned between neighboring sub-pixels PX-P1, PX-P2, and PX-P3 within each second pixel PX-P, and a light blocking layer BM may be positioned between neighboring sub-pixels PX-N1, PX-N2, and PX-N3 within each first pixel PX-N, and may or may not be formed.

FIG. 2 shows an example in which there is no light blocking layer BM between neighboring sub-pixels PX-N1, PX-N2, and PX-N3 within each first pixel PX-N.

A planar shape or width of the light blocking layer BM corresponding to each first pixel PX-N, for example, defining an edge portion of each first pixel PX-N or positioned corresponding to each first pixel PX-N, and the planar shape or width of the light blocking layer BM may be different from the planar shape or width of the light blocking layer BM corresponding to each second pixel PX-P.

In case that a light blocking layer BM is disposed between neighboring sub-pixels PX-N1, PX-N2, and PX-N3 within each first pixel PX-N, the spacing between one light blocking layer BM or the width of the light blocking layer BM may be different from the spacing between neighboring light blocking layers BM or the width of the light blocking layer BM within each corresponding second pixel PX-P.

For example, the spacing between neighboring light blocking layers BM within each first pixel PX-N may be larger than the spacing between neighboring light blocking layers BM within each corresponding second pixel PX-P, and the width of the light blocking layer BM in each first pixel PX-N may be smaller than the width of the light blocking layer BM in each corresponding second pixel PX-P.

The light blocking layer BM may have a first edge portion BO-N that defines the area of each first pixel PX-N. The light blocking layer BM may overlap most of the area of each second pixel PX-P, but may have a second edge portion BO-P that defines each light emitting area LE1-P, LE2-P, or LE3-P.

Referring to FIG. 3, a display device 1000 according to an embodiment may include a substrate SUB, transistors, and light emitting devices formed on the substrate SUB in a cross-sectional structure. The substrate SUB may include an insulating material and may include a transparent material. For example, the substrate SUB may include glass, quartz, or plastic such as polyimide. The substrate SUB may be a rigid substrate or may have flexible characteristics such that the substrate SUB may be curved, bent, folded, or rolled.

A buffer layer BF may be positioned on the substrate SUB. The buffer layer BF may include an inorganic insulating material and/or an organic insulating material including a silicon oxide (SiOₓ), a silicon nitride (SiNₓ), a silicon oxynitride (SiOₓN_{y}), etc., and may be a single layer or multiple layers.

A semiconductor layer ACT may be positioned on the buffer layer BF. The semiconductor layer ACT may include a semiconductor material such as amorphous silicon, polycrystalline silicon, or an oxide semiconductor. The semiconductor layer ACT may include a channel region C, a source region S, and a drain region D. The source region S and drain region D may be disposed on sides (e.g., opposite sides) of the channel region C, respectively. The channel region C may be an intrinsic semiconductor that is not doped with impurities, and the source region S and drain region D may be impurity semiconductors that are doped with conductive impurities and may have conductivity.

A gate insulating layer GI may be positioned on the semiconductor layer ACT. The gate insulating layer GI may include an inorganic insulating material and/or an organic insulating material including a silicon oxide (SiOₓ), a silicon nitride (SiNₓ), a silicon nitride (SiOₓN_{y}), etc., and may be a single layer or a multilayer.

A first conductive layer including a gate electrode GE may be positioned on the gate insulating layer GI. The first conductive layer may be aluminum (Al), platinum (Pt), palladium (Pd), silver (Ag), magnesium (Mg), gold (Au), nickel (Ni), neodymium (Nd), or iridium (Ir). The first conductive layer may include at least one metal or alloy of metals such as chromium (Cr), nickel (Ni), calcium (Ca), molybdenum (Mo), titanium (Ti), tungsten (W), and copper (Cu). The first conductive layer may be formed of a single layer or multiple layers.

An interlayer insulating layer IL1 may be positioned on the gate electrode GE. The interlayer insulating layer IL1 may include an inorganic insulating material and/or an organic insulating material including a silicon oxide (SiOₓ), a silicon nitride (SiNₓ), and a silicon oxynitride (SiOₓN_{y}), and may be a single layer or a multilayer.

A second conductive layer including a source electrode SE and a drain electrode DE may be positioned on the interlayer insulating layer IL1. The source electrode SE and the drain electrode DE may be connected (e.g., electrically connected) to the source region S and the drain region D of the semiconductor layer ACT, respectively, through contact holes formed in the interlayer insulating layer IL1.

A protective layer IL2, which is an insulating layer, may be positioned on the interlayer insulating layer IL1, the source electrode SE, and the drain electrode DE. The protective layer IL2 may cover and planarize the interlayer insulating layer IL1, the source electrode SE, and the drain electrode DE. The protective layer IL2 may include organic and/or inorganic insulating materials such as polymer derivatives, acrylic polymers, imide polymers, polyimide, polyamide, acrylic polymers, and siloxane polymers.

A third conductive layer including the pixel electrode E1 may be positioned on the protective layer IL2. The pixel electrode E1 may be connected (e.g., electrically connected) to the source electrode SE through a contact hole in the protective layer IL2.

The driving transistor, which consists of a gate electrode GE, a semiconductor layer ACT, a source electrode SE, and a drain electrode DE, may be connected (e.g., electrically connected) to the pixel electrode E1 to supply a driving current to the light emitting device ED, which will be described later.

According to an embodiment, the display device 1000 may further include a switching transistor connected to the data line and delivering a data voltage in response to the scan signal, and a compensating transistor connected to the driving transistor and compensating the threshold voltage of the driving transistor in response to the scan signal, in addition to the driving transistor.

A pixel insulating layer PDL may be positioned on the protective layer IL2 and the pixel electrode E1. The pixel insulating layer PDL may have a pixel opening OP that overlaps the pixel electrode E1 and defines a light emitting area. The pixel insulating layer PDL may include an organic insulating material such as polyimide, polyamide, acrylic resin, benzocyclobutene, or phenol resin, or a silica-based inorganic insulating material. The pixel opening OP of the pixel insulating layer PDL may be the light emitting area LE1-N, LE2-N, LE3-N, LE1-P, LE2-P, or LE3-P of the corresponding sub-pixel PX-N1, PX-N2, PX-N3, PX-P1, PX-P2, or PX-P3 may be defined.

An insulating layer PVX may be positioned between the pixel insulating layer PDL and the protective layer IL2. The insulating layer PVX may be a patterned insulating pattern and may have an opening PVO that overlaps the pixel electrode E1.

Each pixel opening OP of the pixel insulating layer PDL may overlap the opening PVO of the corresponding insulating layer PVX. For example, the insulating layer PVX may have an opening PVO corresponding to the pixel opening OP of the pixel insulating layer PDL positioned in each first pixel PX-N.

Referring to FIGS. 2 and 3, the insulating layer PVX may be formed except for the area of the pixel electrode E1 of each first pixel PX-N and each second pixel PX-P shown in FIG. 2, and each first pixel PX-N may include a portion that overlaps an edge portion of the pixel electrode E1. The portion where the edge portion of the pixel electrode E1 and the insulating layer PVX overlap in each first pixel PX-N may correspond to the inclined portion E1-Ca of the curved pixel electrode E1-C, which will be described later.

According to an embodiment, the insulating layer PVX may be formed only in each first pixel PX-N and not in each second pixel PX-P.

The side surface PVS of the insulating layer PVX that defines the opening PVO and is adjacent to the edge portion of the emitting area LE1-N, LE2-N, LE3-N, LE1-P, LE2-P, or LE3-P so a slope inclined toward the third direction DR3 may be formed.

The insulating layer PVX may include an inorganic insulating material and/or an organic insulating material and may be a single layer or multiple layers.

The light emitting layer EML may be positioned on the pixel electrode E1 overlapping the opening PVO and the pixel opening OP.

The light emitting layer EML may include low molecular weight organics or high molecular weight organics such as PEDOT (Poly(3,4-ethylenedioxythiophene). The light emitting layer EML may include one or more of a hole injection layer HIL, a hole transporting layer HTL, an electron transporting layer ETL, and an electron injection layer EIL, and the light emitting layer EML may be a multilayer.

The light emitting layer EML may be positioned mostly within the opening PVO and the pixel opening OP, and may also include portions positioned on the sides and/or top (or upper portion) of the insulating layer PVX and the pixel insulating layer PDL.

A common electrode E2 may be positioned on the light emitting layer EML. The common electrode E2 may be formed of a single conductor across the pixels PX.

The pixel electrode E1, the light emitting layer EML, and the common electrode E2 may together form a light emitting device ED. The pixel electrode E1 may be an anode, which is a hole injection electrode, and the common electrode E2 may be a cathode, which is an electron injection electrode. However, embodiments are not limited thereto, and the pixel electrode E1 may be a cathode and the common electrode E2 may be an anode according to the driving method of the display device 1000.

Holes and electrons may be injected into the light emitting layer EML from the pixel electrode E1 and the common electrode E2, respectively, and light may be emitted in case that an exciton combining the injected holes and electrons falls from the excited state to the ground state.

An encapsulation portion ENC may be positioned on the common electrode E2. The encapsulation portion ENC may cover and seal the light emitting device ED, thereby blocking the inflow of external moisture and oxygen. The encapsulation portion ENC may include a plurality of layers and may include inorganic and organic layers alternately stacked. For example, the encapsulation portion ENC may include an inorganic layer EIL1, an organic layer EOL, and an inorganic layer EIL2 formed sequentially. The encapsulation portion ENC may overlap the front surface of the display area DA in the direction in which the image is displayed, and may be partially disposed on the peripheral area PA.

A light blocking layer BM may be positioned on the encapsulation portion ENC. The light blocking layer BM may have a color such as black and may include a light blocking material. The light blocking layer BM may overlap the pixel insulating layer PDL and the insulating layer PVX. For example, the light blocking layer BM may overlap the pixel insulating layer PDL and the insulating layer PVX where each second pixel PX-P is positioned.

The light blocking layer BM may or may not be positioned between the neighboring light emitting areas LE1-N, LE2-N, and LE3-N of each first pixel PX-N.

Referring to FIG. 4, the pixel insulating layer PDL may be between light emitting areas LE1-P, LE2-P, and LE3-P overlapping a single pixel electrode E1 in each second pixel PX-P, and may further include a pixel insulation pattern PDL-P that defines the boundary. The pixel insulation pattern PDL-P may be positioned in the center portion of the pixel electrode E1.

The light blocking layer BM may be positioned between the light emitting areas LE1-P, LE2-P, and LE3-P overlapping a single pixel electrode E1 at each second pixel PX-P, and may further include a light blocking pattern BM-P defining the boundary. The light blocking pattern BM-P may be positioned in the center portion of the pixel electrode E1 and may overlap the corresponding pixel insulating pattern PDL-P. The viewing angle of light emitted from the light emitting device ED may be limited and reduced by the light blocking layer BM including the light blocking pattern BM-P positioned in each second pixel PX-P.

Accordingly, an image with a viewing angle smaller than the viewing angle of light emitted from the light emitting device ED of each first pixel PX-N may be displayed by each second pixel PX-P.

Referring to FIGS. 3 and 4, the pixel electrodes E1 may include pixel electrodes E1 having different shapes. For example, the pixel electrodes E1 may include a curved pixel electrode E1-C and a flat pixel electrode E1-F having different shapes.

For example, the pixel electrode E1 positioned in each first pixel PX-N may include a curved pixel electrode E1-C, and the pixel electrode E1 positioned in each second pixel PX-P may include a flat pixel electrode E1-F that has a different shape from the curved pixel electrode E1-C, e.g., in the cross-sectional view.

Referring to FIG. 5, the curved pixel electrode E1-C may include at least one curved portion in a cross-sectional view. For example, the curved pixel electrode E1-C may include a flat portion E1-Cb and a flat portion E1-Cb extending in a direction perpendicular to the third direction DR3 or parallel to the surface of the substrate SUB, and may include an inclined portion E1-Ca that is oblique with respect to the third direction DR3 and the surface of the substrate SUB. The flat portion E1-Cb and the inclined portion E1-Ca may be formed of a single physically connected conductive layer (or an integrated conductive layer). The inclined portion E1-Ca may be positioned along the edge portion of the curved pixel electrode E1-C.

Referring to FIGS. 2 and 5, a portion of the inclined portion E1-Ca of the curved pixel electrode E1-C may correspond to the edge area excluding the light emitting area LE1-N, LE2-N, or LE3-N among the areas of each pixel electrode E1 of each first pixel PX-N in the plan view of FIG. 2.

The inclined portion E1-Ca may be positioned on the side surface PVS, which is an inclined surface of the insulating layer PVX. Accordingly, the curved pixel electrode E1-C may have a concave shape according to the shape of the side surface PVS of the protective layer IL2 and the insulating layer PVX positioned below.

For example, the flat pixel electrode E1-F may not include a portion formed on the side surface PVS of the insulating layer PVX and may therefore include only a flat portion parallel to the surface of the substrate SUB.

Referring to FIG. 5, light may be emitted from the flat portion E1-Cb of the curved pixel electrode E1-C or the light emitting layer EML on the flat pixel electrode E1-F or is emitted from the light emitting layer EML. Light that is reflected and incident on the flat portion E1-Cb of the curved pixel electrode E1-C or the flat pixel electrode E1-F may be emitted as light L1 to the front of the display device 1000.

The light from the light emitting layer EML disposed on the inclined portion E1-Ca of the curved pixel electrode E1-C, or the light that is emitted from the light emitting layer EML and reflected to be incident on the inclined portion E1-Ca of the curved pixel electrode E1-C, may emit light L2 in the lateral direction, which is an angle greater than 0 degrees with respect to the third direction DR3. Therefore, in the normal mode (or wide-viewing angle mode) driven by including each first pixel PX-N, the luminance of the image viewed in the side direction may be increased by increasing the amount of light emitted from each first pixel PX-N in the side direction. Accordingly, it is possible to improve the degradation of luminance ratio characteristics due to changes in viewing angle in the normal mode of a display device 1000 that is selectively driven in a private mode (or narrow-viewing angle mode) and a normal mode (or wide-viewing angle mode), and to reduce degradation of image quality such as color shift.

All of the first sub-pixel PX-N1, the second sub-pixel PX-N2, and the third sub-pixel PX-N3 included in the first pixels PX-N may include a pixel electrode E1-C. In another example, only sub-pixels of some colors among the first sub-pixel PX-N1, the second sub-pixel PX-N2, and the third sub-pixel PX-N3 may include a curved pixel electrode E1-C and the remainder may include a flat pixel electrode E1-F.

For example, only the first sub-pixel PX-N1 such as a red pixel may include a curved pixel electrode E1-C according to an embodiment, and the second and third sub-pixels PX-N2 and PX-N3 such as green and blue pixels may include a flat pixel electrode E1-F.

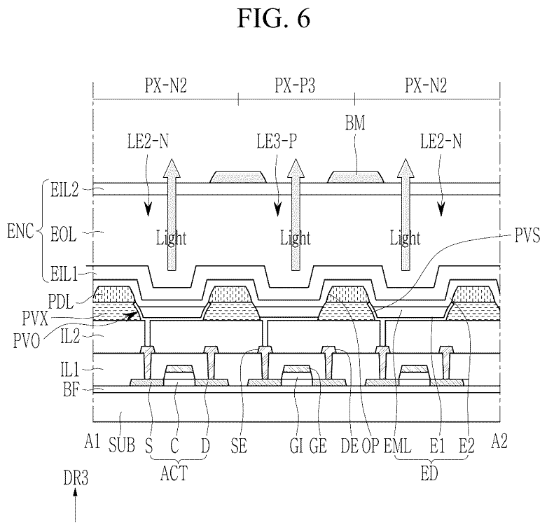

An image display method of a display device 1000 according to an embodiment and the previously described effects will be described with reference to FIGS. 6 to 9 along with the previously described drawings.

FIG. 6 is a schematic cross-sectional view of the display device 1000 shown in FIG. 2 taken along line A1-A2, showing light emitted from the front of the display device 1000 in a normal mode (or wide-viewing angle mode).

Referring to FIG. 6, in a normal mode, a display device 1000 according to an embodiment may drive first pixels PX-N and second pixels PX-P together to display each first pixel PX-N, and light may be emitted from light emitting areas LE1-N, LE2-N, LE3-N, LE1-P, LE2-P, and LE3-P of each second pixel PX-P.

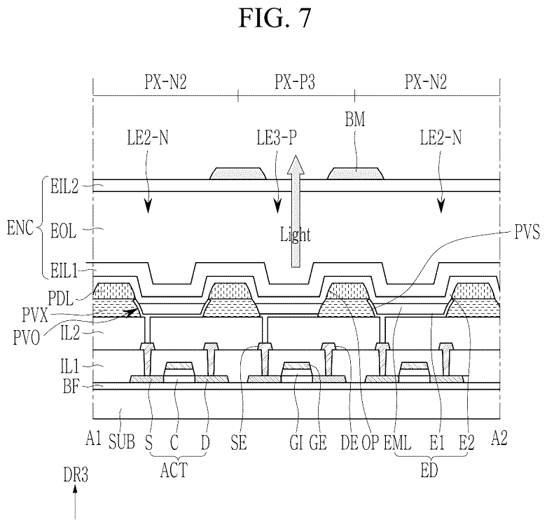

FIG. 7 is a schematic cross-sectional view of the display device 1000 shown in FIG. 2 taken along line A1-A2 and shows light emitted from the front of the display device 1000 in a private mode (or narrow-viewing angle mode).

Referring to FIG. 7, in a private mode (or narrow-viewing angle mode), a display device 1000 according to an embodiment may drive only second pixels PX-P, so that light may be emitted from light emitting areas LE1-P, LE2-P, and LE3-P of each second pixel PX-P. In a private mode, light may be emitted from the front, and light emitted from the third direction DR3 and the side, which is a direction greater than 0 degrees, is blocked by the light blocking layer BM, displaying the image to be displayed at a narrow viewing angle.

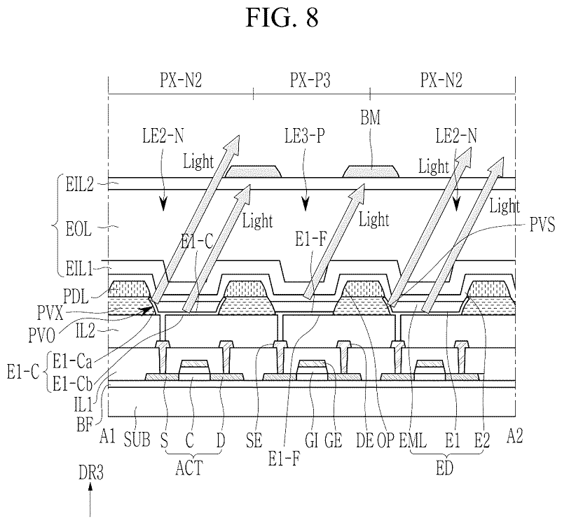

FIG. 8 is a schematic cross-sectional view of the display device 1000 shown in FIG. 2 taken along line A1-A2 and shows light emitted to the side in a normal mode (or wide-viewing angle mode).

Referring to FIG. 8, the light emitted from the light emitting layer EML on the flat portion E1-Cb of the curved pixel electrode E1-C included in some first pixel PX-N may be blocked by the light blocking layer BM like each second pixel PX-P, which reduces the luminance from the side direction in a normal mode. However, the curved pixel electrode E1-C of each first pixel PX-N of the display device 1000 according to an embodiment includes a sloping portion (or inclined portion) E1-Ca, the light emitted from the light emitting layer EML on the sloping portion E1-Ca or reflected from the sloping portion E1-Ca is emitted in the lateral direction, and the ratio blocked by the light blocking layer BM is small. Thus, the decrease in luminance in the lateral direction may be compensated or prevented, and the degradation of image quality such as color shift may be reduced or minimized by improving the luminance ratio characteristics according to the change of viewing angle in a normal mode.

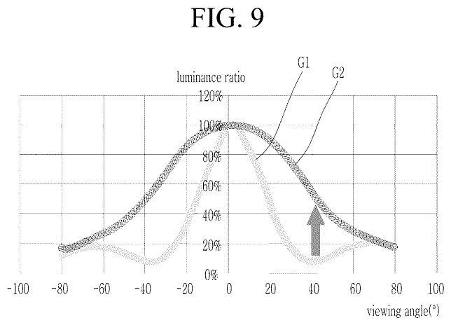

FIG. 9 is a graph showing the luminance ratio according to the viewing angle of an image displayed by a display device 1000 according to an embodiment and a comparative example.

Referring to FIG. 9, the graph G1 represents the change in luminance ratio according to the viewing angle of the image (for example, white) displayed in the normal mode (or wide-viewing angle mode) of the display device 1000 according to the comparative example in which the pixel electrode E1 of each first pixel PX-N does not include the inclined portion E1-Ca unlike the embodiment described above, and each second pixel PX-P for implementing the private mode (or narrow-viewing angle mode) may include the inclined portion E1-Ca, and the graph G2 represents the luminance ratio according to the change in viewing angle of the image (for example, white) displayed in the normal mode of the display device 1000 according to an embodiment.

According to an embodiment, as indicated by an arrow, luminance may be increased at a side viewing angle in the normal mode of a display device 1000 including a second pixel PX-P for implementing a private mode, and luminance ratio characteristics according to changes in viewing angle, by improving degradation, image quality degradation such as color shift may be reduced.

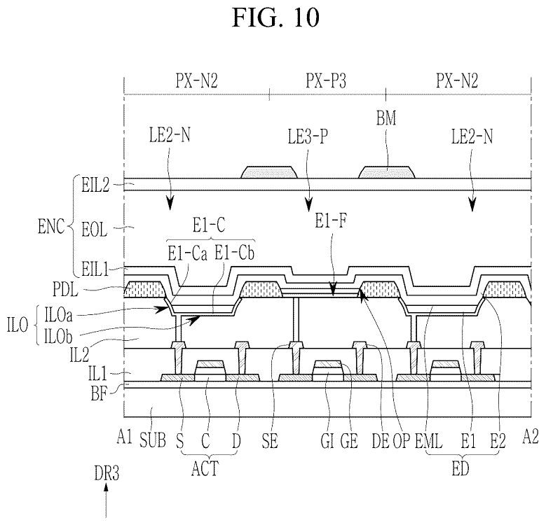

A display device 1000 according to an embodiment will be described with reference to FIG. 10 along with the previously described drawings.

FIG. 10 is a schematic cross-sectional view of the display device 1000 shown in FIG. 2 taken along line A1-A2.

Referring to FIG. 10, the display device 1000 according to an embodiment is mostly the same as the display device 1000 according to the previously described embodiment, but the structure for forming the curved pixel electrode E1-C may be different.

Unlike the previously described embodiment, the insulating layer PVX may be omitted.

For example, the protective layer IL2, which is an insulating layer positioned directly below the pixel electrode included in each first pixel PX-N, may have a top surface (or upper surface) where a concave portion ILO corresponding to the pixel electrode E1 of the sub-pixels PX-N1, PX-N2, and PX-N3 is formed.

The concave portion ILO may overlap each pixel opening OP of the pixel insulating layer PDL in each first pixel PX-N. The concave portion ILO of the protective layer IL2 may include a flat surface ILOb that is generally parallel to the upper surface of the substrate SUB and a side surface ILOa that is inclined with respect to the third direction DR3.

Referring to FIGS. 2 and 10, the concave portion ILO may overlap the central portion excluding the edge portion of the pixel electrode E1 of each first pixel PX-N, and the side surface ILOa of the concave portion ILO may overlap the edge portion of the pixel electrode E1 of each first pixel PX-N. The concave portion ILO may not be formed in each second pixel PX-P.

The flat portion E1-Cb of the curved pixel electrode E1-C of each first pixel PX-N may be positioned on the flat surface ILOb of the concave portion ILO, and the inclined portion E1-Ca may be positioned on the side surface ILOa of the concave portion ILO. Accordingly, the curved pixel electrode E1-C may have a concave shape according to the shape of the concave portion ILO of the protective layer IL2 positioned below. The concave portion ILO according to an embodiment may be formed using a halftone mask during the manufacturing process of the display device 1000.

Although the embodiments have been described in detail above, the scope of the invention is not limited thereto, and various modifications and improvements may be made by those skilled in the art using the basic concepts of the invention defined in the following claims.

What is claimed is:

1. A display device comprising:
a plurality of first pixels and a plurality of second pixels alternately arranged, and
a driver that drives the plurality of first pixels and the plurality of second pixels by individually applying a driving signal and a voltage, wherein
each of the plurality of first pixels includes a first transistor and a first pixel electrode electrically connected to the first transistor,
each of the plurality of second pixels includes a second transistor and a second pixel electrode electrically connected to the second transistor, and
the first pixel electrode and the second pixel electrode have different shapes from each other in a cross-sectional view.

2. The display device of claim 1, wherein
the first pixel electrode includes at least one curved portion in a cross-sectional view.

3. The display device of claim 2, wherein
the first pixel electrode includes:
a flat portion extending in a first direction, and
an inclined portion connected to the flat portion and slanted with respect to the first direction.

4. The display device of claim 3, wherein
the inclined portion is disposed along an edge portion of the first pixel electrode.

5. The display device of claim 3, wherein
the second pixel electrode includes a flat portion extending in the first direction.

6. The display device of claim 3, further comprising:
a first insulating layer disposed on the first transistor and the second transistor, and
a second insulating layer disposed on the first insulating layer, and
the second insulating layer has a first opening overlapping the first pixel electrode.

7. The display device of claim 6, wherein
the inclined portion of the first pixel electrode is disposed on a side surface of the second insulating layer defining the first opening.

8. The display device of claim 6, further comprising:
a pixel insulating layer disposed on the second insulating layer, wherein
the pixel insulating layer has a second opening overlapping the first pixel electrode and the second pixel electrode.

9. The display device of claim 6, wherein
each of the plurality of first pixels and each of the plurality of second pixels includes a plurality of sub-pixels displaying light of different colors,
each of the plurality of sub-pixels disposed in each of the plurality of first pixels includes the first pixel electrode, and
the first pixel electrode included in at least some of the plurality of sub-pixels included in each of the plurality of first pixels includes the inclined portion.

10. The display device of claim 3, further comprising:
a first insulating layer disposed on the first transistor and the second transistor, wherein
a concave portion overlapping the first pixel electrode is formed on an upper surface of the first insulating layer, and
the inclined portion of the first pixel electrode is disposed on a side surface of the concave portion.

11. A display device comprising:
a plurality of first pixels and a plurality of second pixels alternately arranged, and
a light blocking layer, wherein
a planar shape or a width of the light blocking layer corresponding to each of the plurality of first pixels or defining an edge portion of each of the plurality of first pixels is different from a planar shape or a width of the light blocking layer corresponding to each of the plurality of second pixels,
each of the plurality of first pixels includes a first transistor and a first pixel electrode electrically connected to the first transistor,
each of the plurality of second pixels includes a second transistor and a second pixel electrode electrically connected to the second transistor, and
the first pixel electrode and the second pixel electrode have different shapes from each other in a cross-sectional view.

12. The display device of claim 11, wherein
the first pixel electrode includes at least one curved portion in a cross-sectional view.

13. The display device of claim 12, wherein
the first pixel electrode includes:
a flat portion extending in a first direction, and
an inclined portion connected to the flat portion and slanted with respect to the first direction.

14. The display device of claim 13, wherein
the inclined portion is disposed along an edge portion of the first pixel electrode.

15. The display device of claim 13, wherein
the second pixel electrode includes a flat portion extending in the first direction.

16. The display device of claim 13, further comprising:
a first insulating layer disposed on the first transistor and the second transistor, and
a second insulating layer disposed on the first insulating layer,
wherein the second insulating layer has a first opening overlapping the first pixel electrode.

17. The display device of claim 16, wherein
the inclined portion of the first pixel electrode is disposed on a side surface of the second insulating layer defining the first opening.

18. The display device of claim 16, further comprising:
a pixel insulating layer disposed on the second insulating layer,
wherein the pixel insulating layer has a second opening overlapping the first pixel electrode and the second pixel electrode.

19. The display device of claim 16, wherein
each of the plurality of first pixels and each of the second plurality of pixels includes a plurality of sub-pixels displaying light of different colors,
each of the plurality of sub-pixels disposed in each of the plurality of first pixels includes the first pixel electrode, and
the first pixel electrode included in at least some of the plurality of sub-pixels included in each of the plurality of first pixels includes the inclined portion.

20. The display device of claim 13, further comprising:
a first insulating layer disposed on the first transistor and the second transistor, wherein
a concave portion overlapping the first pixel electrode is formed on an upper surface of the first insulating layer, and
the inclined portion of the first pixel electrode is disposed on a side surface of the concave portion.
